(19) United States
(12) Patent Application Publication
(10) Pub. No.: US 2024/0106200 A1
(43) Pub. Date: Mar. 28, 2024

(54) OPTICAL DEVICE THAT INCLUDES AN EPITAXIAL LAYER STRUCTURE WITH TRENCHES AND GROOVES

(71) Applicant: Lumentum Operations LLC, San Jose, CA (US)

(72) Inventors: Li FAN, Milpitas, CA (US); Victor ROSSIN, Mountain View, CA (US)

(21) Appl. No.: 18/060,203

(22) Filed: Nov. 30, 2022

Related U.S. Application Data
(60) Provisional application No. 63/377,252, filed on Sep. 27, 2022.

(51) Int. Cl. H01S 5/20; H01S 5/22

(52) U.S. Cl. CPC H01S 5/2036; H01S 5/22

(57) ABSTRACT

An optical device includes a substrate and an epitaxial layer structure disposed over the substrate. The epitaxial layer structure includes a first clad layer disposed over the substrate, a first waveguide layer disposed over the first clad layer, an active layer disposed over the first waveguide layer, a second waveguide layer disposed over the active layer, a second clad layer disposed over the second waveguide layer, and a cap layer disposed over the second clad layer. The optical device further includes a pair of trenches formed in an inner region of a surface of the epitaxial layer structure, and a pair of grooves, each formed in an outer region of the surface of the epitaxial layer structure. Each trench does not extend into the active layer, and each groove extends into the active layer. A light-current curve associated with the laser optical device is kink-free and/or smooth.

### CROSS-REFERENCE TO RELATED APPLICATION

This patent application claims priority to U.S. Provisional Application No. 63/377,252, filed on Sep. 27, 2022, and entitled “KINK-FREE, HIGH FILL FACTOR, HIGH POWER BROAD AREA DIODE LASER WITH A SMALL SLOW AXIS DIVERGENCE ANGLE.” The disclosure of the prior application is considered part of and is incorporated by reference into this patent application.

### TECHNICAL FIELD

The present disclosure relates generally to an optical device and to an optical device that includes an epitaxial structure with trenches and grooves.

### BACKGROUND

A broad area laser diode is an edge-emitting laser diode, where an emitting region of a front facet of the broad area laser diode has a shape of a broad stripe or ridge. The fill factor of the broad area laser diode is defined as a percentage (or ratio) of a width of the emitting region compared to a width of the broad area laser diode.

### SUMMARY

In some implementations, an optical device includes a substrate; an epitaxial layer structure disposed over the substrate that includes: a first clad layer disposed over the substrate, a first waveguide layer disposed over the first clad layer, an active layer disposed over the first waveguide layer, a second waveguide layer disposed over the active layer, a second clad layer disposed over the second waveguide layer, and a cap layer disposed over the second clad layer; a pair of trenches formed in an inner region of a surface of the epitaxial layer structure; and a pair of grooves, each formed in an outer region of the surface of the epitaxial layer structure.

In some implementations, an optical device includes an epitaxial layer structure that includes an active layer; a pair of trenches formed in an inner region of a surface of the epitaxial layer structure; and a pair of grooves formed in outer regions of the surface of the epitaxial layer structure, wherein each groove, of the pair of grooves, has a depth that is greater than a depth of each trench of the pair of trenches.

In some implementations, a laser device includes an epitaxial layer structure; a pair of trenches formed in an inner region of a surface of the epitaxial layer structure; and a pair of grooves formed in outer regions of the surface of the epitaxial layer structure.

### BRIEF DESCRIPTION OF THE DRAWINGS

FIGS. 1A-1D are diagrams of example implementations described herein.

FIGS. 2A-2B are diagrams of examples of light-current (L-I) curves associated with optical devices.

### DETAILED DESCRIPTION

The following detailed description of example implementations refers to the accompanying drawings. The same reference numbers in different drawings may identify the same or similar elements.

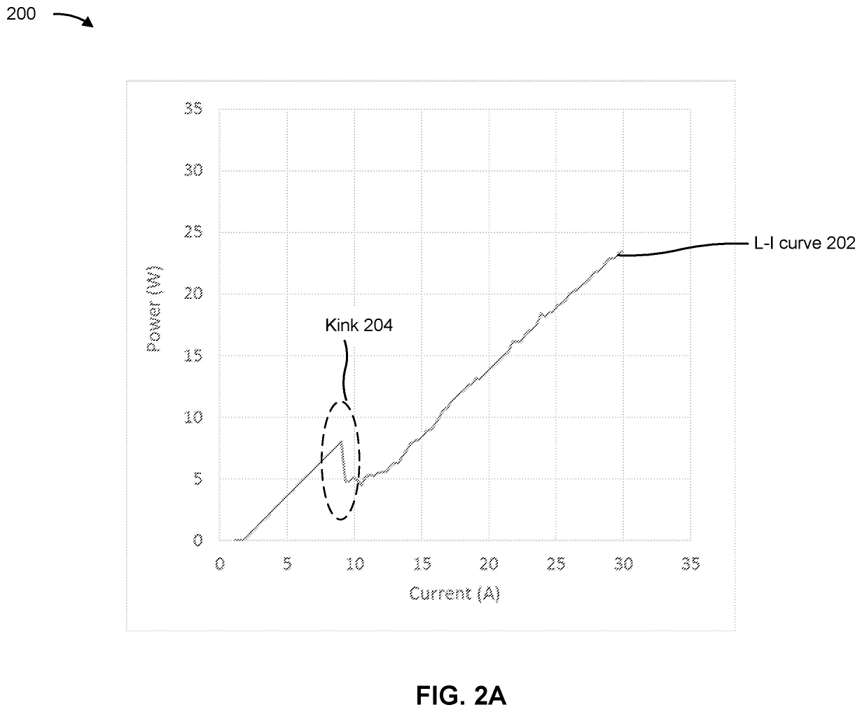

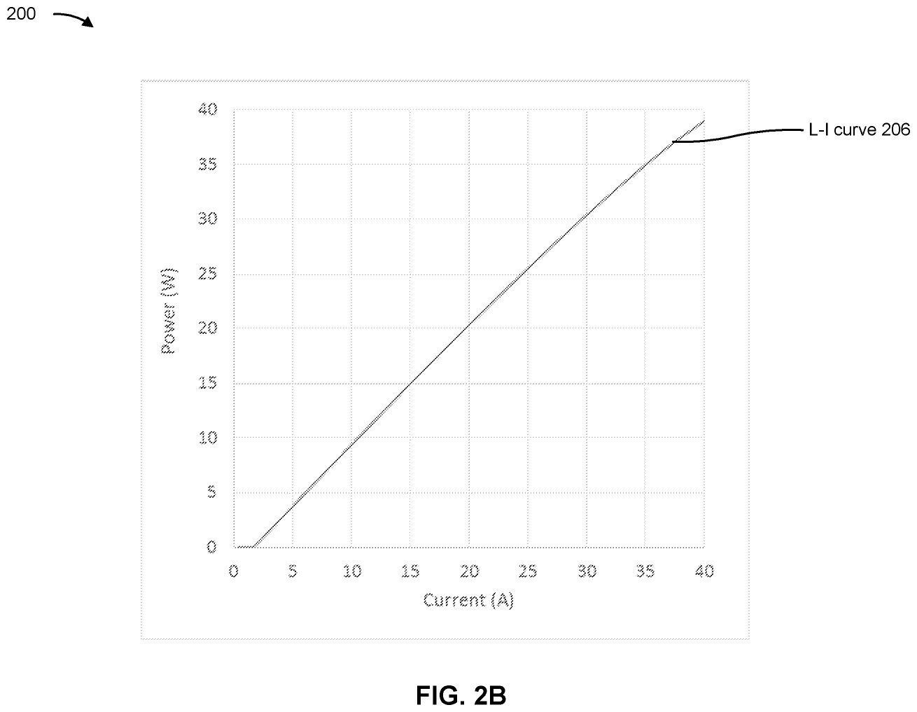

To achieve a high power output (e.g., a high optical power output) of a laser device, such as a broad area laser diode device, and to reduce a size of the laser device and/or a cost associated with manufacturing the laser device, a high fill factor of the laser device is preferred. For example, a fill factor that is greater than or equal to 60% is often preferred. However, in many cases, such a high fill factor enables formation of non-preferred in-epitaxial-plane (in-epi-plane) lasing within the laser device. For example, a high fill factor often enables formation of ring modes and/or other non-preferred in-epi-plane lasing modes within an epitaxial layer structure of the laser device. This causes a power performance (e.g., an optical power performance) of the laser device to not be consistent or predictable (e.g., when a current applied to laser device changes). This is indicated by a light-current (L-I) curve associated with the laser device, which often has a kink and is not smooth (e.g., as described herein in relation to FIG. 2A). Consequently, the laser device cannot be used in applications where a more consistent and predictable power performance is desired.

In some cases, the laser device can include trenches (e.g., that define a ridge of the laser device) that extend deeply into the epitaxial layer structure of the laser device to minimize the kink in the L-I curve of the laser device. However, including deep trenches in the laser device results in a large horizontal far field divergence angle (a large slow-axis divergence angle), which reduces a brightness of the laser device.

Some implementations described herein provide an optical device (e.g., a laser device, such as a broad area laser diode device) that includes a pair of trenches and a pair of grooves formed in a surface of an epitaxial layer structure of the optical device. A width and depth of the pair of trenches may be configured to minimize a slow axis far field divergence angle of the optical device. A width and depth of the pair of grooves may be configured to minimize, or to prevent, in-epi-plane lasing within the epitaxial layer structure. For example, the pair of grooves may extend into at least an active layer of epitaxial layer structure of the optical device, which minimizes, or prevents, formation of ring modes and/or other non-preferred in-epi-plane lasing modes within the epitaxial layer structure. As another example, a sidewall of each groove may be rough and/or non-planar, and corresponding sidewalls of the pair of grooves may not be parallel to each other, which reduces a likelihood that conditions for total internal reflection within the epitaxial layer structure are satisfied. This additionally minimizes, or prevents, formation of ring modes and/or other non-preferred in-epi-plane lasing modes within the epitaxial layer structure.

In this way, even when the optical device has a high fill factor (e.g., a fill factor that is greater than or equal to 60%), a power performance of the optical device (e.g., when changing the current of the optical device) is more consistent and predictable than that of the laser device described above. This is indicated by an L-I curve associated with the optical device, which does not have a kink (e.g., is “kink-free”) and is smooth (e.g., as described herein in relation to FIG. 2B). Further, the power performance of the optical device is more efficient because applying an increased current to the optical device reliably results in an increased power of the optical device. Accordingly, the optical device can be used in applications where a more consistent and predictable power performance is required (and in which the laser device described above cannot be used). Further, because the optical device prevents the slow axis far field divergence angle from exceeding the divergence angle threshold, a brightness of the optical device is maintained.

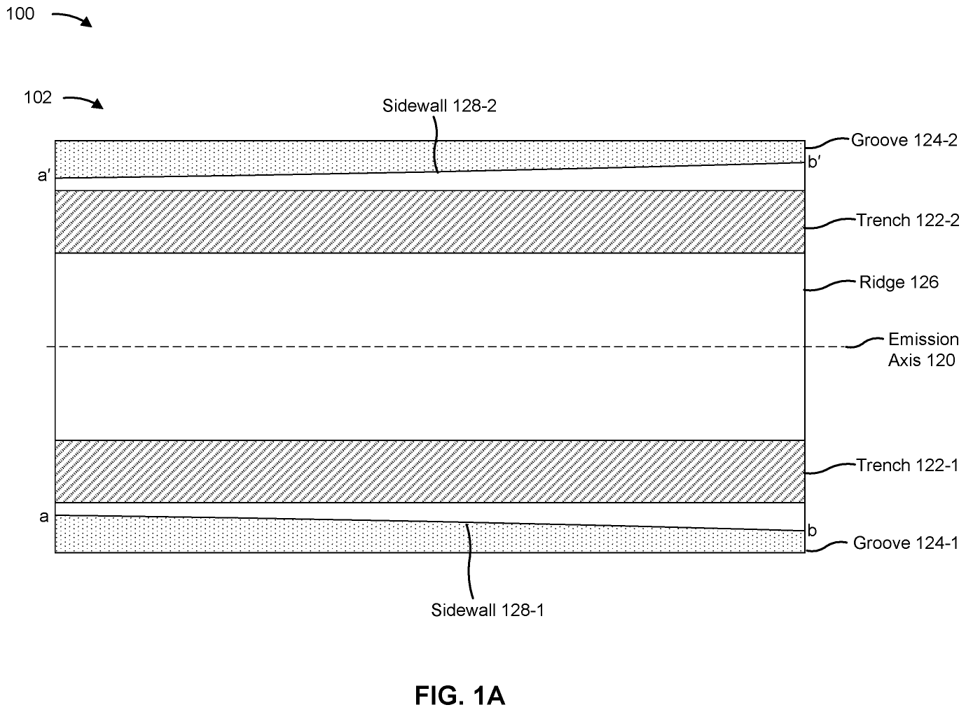

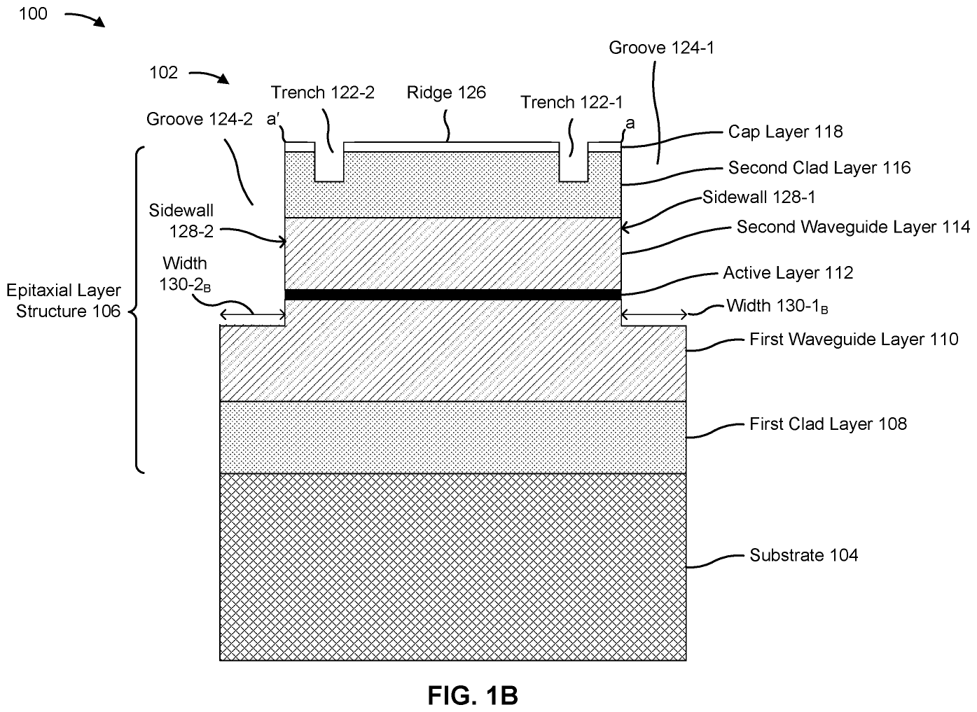

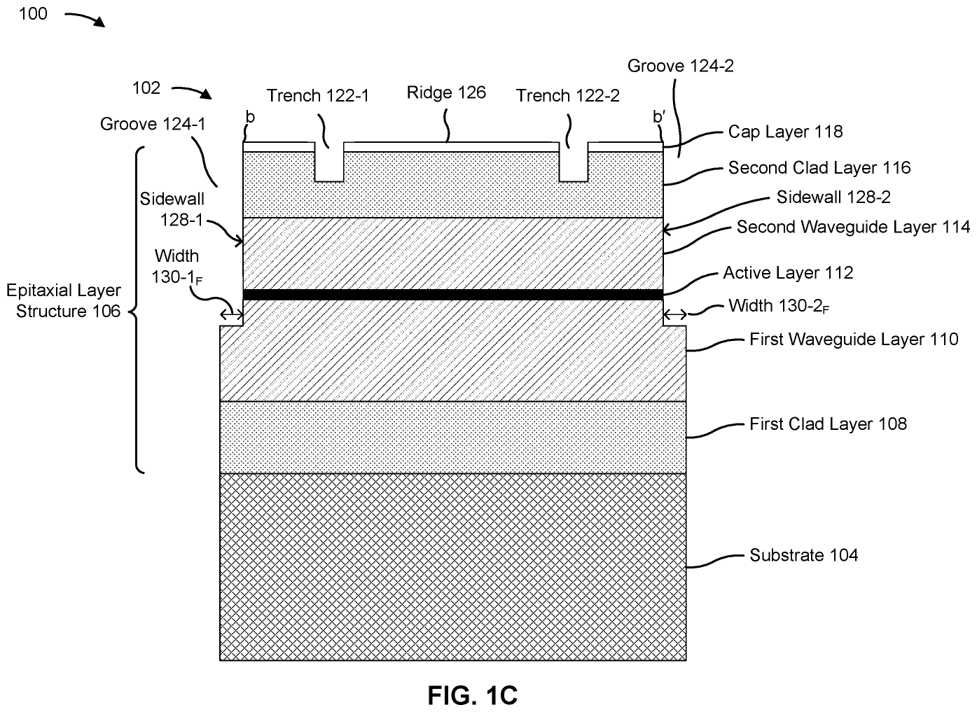

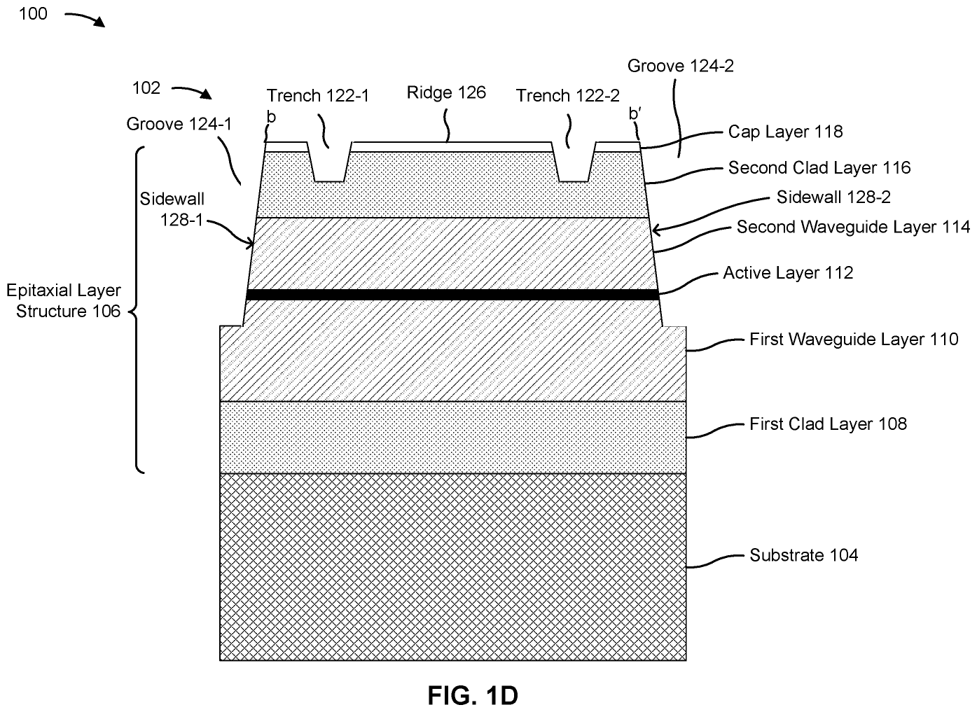

FIGS. 1A-1D are diagrams of example implementations 100 described herein. As shown in FIGS. 1A-1D, each example implementation 100 may include an optical device 102. FIG. 1A shows a top-down view of the optical device 102; FIG. 1B shows a back-end view of the optical device 102 (e.g., from the left side of the optical device 102 as shown in FIG. 1A); FIG. 1C shows a front-end view of the optical device 102 (e.g., from the right side of the optical device 102 as shown in FIG. 1A); and FIG. 1D shows a back-end view of another configuration of the optical device 102.

As shown in FIGS. 1B-1D, the optical device 102 may include a substrate 104 and an epitaxial layer structure 106 that is disposed over (e.g., directly on, or indirectly on) the substrate 104 (e.g., a top surface of the substrate 104). The epitaxial layer structure 106 may comprise a first clad layer 108 (e.g., disposed over the substrate 104), a first waveguide layer 110 (e.g., disposed over the first clad layer 108), an active layer 112 (e.g., disposed over the first waveguide layer 110), a second waveguide layer 114 (e.g., disposed over the active layer 112), a second clad layer 116 (e.g., disposed over the second waveguide layer 114), and/or a cap layer 118 (e.g., disposed over the second clad layer 116).

The optical device 102 may be a laser device or another type of light-emitting device. For example, the optical device 102 may be a broad area laser device configured to emit a laser beam, such as a near infrared (NIR) laser beam (e.g., a laser beam associated with a spectral range of 700 nanometers (nm) to 1600 nm). The optical device 102 may be configured to generate, propagate, and emit the laser beam along an emission axis 120 (e.g., from the back end of the optical device 102 to the front end of the optical device 102, or vice versa).

The substrate 104 may be a gallium arsenide (GaAs) substrate, an indium phosphide (InP) substrate, or another substrate (e.g., with a Bravais lattice structure). Additionally, or alternatively, the substrate 104 may be doped. For example, the substrate 104 may be an n-doped substrate. The substrate 104 may be formed from a wafer (e.g., a slice) from a boule, and various other layers of the epitaxial layer structure 106 may be formed (e.g., grown) over the substrate 104 (e.g., over a top surface of the substrate 104 as shown in FIGS. 1B-1D).

The first clad layer 108 may be configured to confine light (e.g., of a laser beam) within the first waveguide layer 110, the active layer 112, and/or the second waveguide layer 114. Additionally, or alternatively, the first clad layer 108 may be doped. For example, the first clad layer 108 may be an n-doped clad layer. The first waveguide layer 110 may be configured to guide light (e.g., of a laser beam) in a particular direction within the optical device 102 (e.g., along the emission axis 120 of the optical device 102), and/or to confine the light within the active layer 112. The active layer 112 may be configured to act as an active region of the optical device 102 (e.g., act as a laser active region within a laser cavity when the epitaxial layer structure 106 is included in a laser device). The active layer 112 may include one or more quantum wells. The second waveguide layer 114 may be configured to guide light (e.g., of a laser beam) in the particular direction within the optical device 102 (e.g., along the emission axis 120 of the optical device 102), and/or to confine the light within the active layer 112. The second clad layer 116 may be configured to confine light (e.g., of a laser beam) within the first waveguide layer 110, the active layer 112, and/or the second waveguide layer 114. Additionally, or alternatively, the second clad layer 116 may be doped. For example, the second clad layer 116 may be a p-doped clad layer. The cap layer 118 may be configured to protect the other layers of the epitaxial layer structure 106 (e.g., when the cap layer 118 is formed as a top layer of the epitaxial layer structure 106). The cap layer 118 may be highly doped. For example, the cap layer 118 may be a highly doped p-doped cap layer.

As shown in FIGS. 1A-1D, the optical device 102 may include a pair of trenches 122 (shown as trenches 122-1 and 122-2) and a pair of grooves 124 (shown as grooves 124-1 and 124-2). For example, as shown in FIG. 1A, the pair of trenches 122 and the pair of grooves 124 may be formed in a surface (e.g., a top surface) of the optical device 102. That is, as shown in FIGS. 1B-1D, the pair of trenches 122 and the pair of grooves 124 may be formed in a surface (e.g., a top surface) of the epitaxial layer structure 106 that comprises the surface of the optical device 102.

As shown in FIG. 1A, the pair of trenches 122 may be formed in an inner region (e.g., a central region) of the surface of the optical device 102 (e.g., an inner region of the surface of the epitaxial layer structure 106). The pair of trenches 122 may be formed along a dimension of the inner region of the surface of the optical device 102 (e.g., along a dimension of the inner region of the surface of the epitaxial layer structure 106) that is substantially parallel to (e.g., within a tolerance, which may be less than or equal to 1 degree, 2 degrees, and/or 3 degrees, among other examples) to the emission axis 120. For example, as shown in FIG. 1A, the pair of trenches 122 may be formed along a length (e.g., shown as a horizontal dimension) of the inner region of the surface of the optical device 102.

In some implementations, the pair of trenches 122 may define a ridge 126 of the optical device 102 (e.g., a ridge 126 of the epitaxial layer structure 106). For example, as shown in FIGS. 1A-1D, the ridge 126 may be an area of the inner region of the surface of the optical device 102 that is bounded by the pair of trenches 122. In some implementations, a width of the ridge 126 may be defined as distance between inner-facing edges of the pair of trenches 122. A fill factor of the optical device 102 may be defined as a percentage (or ratio) of the width of the ridge 126 as compared to a width of the optical device 102. In some implementations, the fill factor of the optical device 102 may satisfy a fill factor threshold. That is, the fill factor may be greater than or equal to the fill factor threshold, which may be greater than or equal to, for example, 60%, 61%, 62.5%, or 65%.

In some implementations, the pair of trenches 122 may be formed using an etching technique (e.g., using a wet etching technique or a dry etching technique). In some implementations, each trench 122, of the pair of trenches 122, may extend into at least the second clad layer 116. For example, as shown in FIGS. 1B-1D, each trench 122 may extend through the cap layer 118 into the second clad layer 116. In some implementations, each trench 122 does not extend into the second waveguide layer 114 and/or does not extend into the active layer 112. In this way, each trench 122 may have a depth that is less than a depth of each groove 124 (as further described herein). In some implementations, each trench 122 may have sidewalls that are substantially parallel (e.g., within a tolerance, which may be less than or equal to 1 degree, 2 degrees, and/or 3 degrees, among other examples) to an epitaxial formation axis of the optical device 102 (e.g., a vertical direction, as shown in FIGS. 1B-1D), such as due to a dry etching technique. Accordingly, each trench 122 may have “vertical” sidewalls, such as shown in FIGS. 1B-1C. Alternatively, each trench 122 may have sidewalls that are at a non-zero angle to the epitaxial formation axis, such as due to using a wet etching technique. Accordingly, each trench 122 may have “non-vertical” sidewalls, such as shown in FIG. 1D.

In some implementations, the pair of trenches 122 may be formed to have a particular depth and/or width, such that the pair of trenches 122 are configured to cause a slow axis far field divergence angle associated with the optical device 102 to satisfy a divergence angle threshold. That is, the pair of trenches 122 may be configured to cause the slow axis far field divergence angle associated with the optical device 102 to be less than or equal to the divergence angle threshold, which may be less than or equal to 7 degrees, 10 degrees, or 15 degrees, among other examples. For example, the depth and/or width of the pair of trenches 122 may define an effective refractive index contrast of the second waveguide layer 114 (e.g., in the slow axis direction). In this way, the pair of trenches 122 may be formed to prevent the slow axis far field divergence angle associated with the optical device 102 from exceeding the divergence angle threshold.

As shown in FIG. 1A, the pair of grooves 124 may each be formed in an outer region (e.g., a perimeter region) of the surface of the optical device 102 (e.g., an outer region of the surface of the epitaxial layer structure 106). As further shown in FIG. 1A, each groove 124 may be formed along an edge (e.g., a vertical edge, as shown in FIG. 1A) of the outer region of the optical device 102.

The pair of grooves 124 may be formed using an etching technique (e.g., a same, or different, etching technique as that used to form the pair of trenches 122). In some implementations, each groove 124 may extend into at least the active layer 112. For example, as shown in FIGS. 1B-1D, each groove 124 may extend through the cap layer 118, through the second clad layer 116, through the second waveguide layer 114, through the active layer 112, and into the first waveguide layer 110. In this way, each groove 124 may have a depth that is greater than a depth of each trench 122.

In some implementations, each groove 124 may be formed to have a sidewall 128. For example, as shown in FIG. 1A, a first groove 124-1 (e.g., the bottom groove 124 shown in FIG. 1A) may have a first sidewall 128-1 that extends from a to b, and a second groove 124-2 (e.g., the top groove 124 shown in FIG. 1A) may have a sidewall 128-2 that extends from a′ to b′. In some implementations, the sidewall 128 of each groove 124 may be substantially parallel (e.g., within a tolerance, which may be less than or equal to 1 degree, 2 degrees, or 3 degrees, among other examples) to an epitaxial formation axis of the optical device 102 (e.g., a vertical direction, as shown in FIGS. 1B-1D), such as due to a dry etching technique. Accordingly, the sidewall 128 may be a “vertical” sidewall, such as shown in FIGS. 1B-1C. Alternatively, the sidewall 128 may be at a non-zero angle to the epitaxial formation axis, such as due to using a wet etching technique. Accordingly, each sidewall 128 may have “non-vertical” sidewalls, such as shown in FIG. 1D.

In some implementations, the sidewall 128 of each groove 124 may be rough. For example, the sidewall 128 may be diffusive and/or is otherwise configured to spread light that impinges on the sidewall 128. Additionally, or alternatively, the sidewall 128 may be non-planar (e.g., may have a serrated, stepped, curved, and/or other profile that is not planar). For example, as shown in FIG. 1A, the first sidewall 128-1 and the second sidewall 128-2 may be partially curved. Additionally, or alternatively, the sidewall 128 may be oriented to not be parallel to the emission axis 120 of the optical device 102. For example, the sidewall 128 may be oriented at a non-zero angle to the emission axis 120, such that the non-zero angle is greater than a non-zero angle threshold (e.g., that is greater than or equal to 1 degree, 2 degrees, 3 degrees, or 5 degrees, among other examples). Accordingly, a width 130 of each groove 124 may vary along a dimension of the optical device 102 (e.g., a dimension that is parallel to the emission axis 120). For example, as shown in FIG. 1B, which shows the back-end view of the optical device 102, the first groove 124-1 may have a width 130-1B and the second groove 124-2 may have a width 130-2B at the front of the optical device 102. As shown in FIG. 1C, which shows the front-end view of the optical device 102, the first groove 124-1 may have a width 130-1F and the second groove 124-2 may have a width 130-2F at the back of the optical device 102. As shown in FIGS. 1B-1C, the width 130-1B may be different than the width 130-1F (e.g., the width 130-1B may be greater than the width 130-1F), and the width 130-2B may be different than the width 130-2F (e.g., the width 130-2B may be greater than the width 130-2F).

In this way, when each groove 124 extends into at least the active layer 112 and/or the sidewall 128 of each groove 124 is rough, non-planar, and/or not parallel to the emission axis 120, and/or, each groove 124 may be configured to minimize, or to prevent, in-epi-plane lasing within the epitaxial layer structure 106. For example, by extending into at least the active layer 112, each groove 124 impacts the active layer 112 and thereby minimizes, or prevents, formation of ring modes and/or other non-preferred in-epi-plane lasing modes within the epitaxial layer structure 106. As another example, by forming the sidewall 128 of each groove 124 to be rough, non-planar, and/or not parallel to the emission axis 120, each groove 124 reduces a likelihood that conditions for total internal reflection within the epitaxial layer structure 106, which additionally minimizes, or prevents, formation of ring modes and/or other non-preferred in-epi-plane lasing modes within the epitaxial layer structure 106.

As indicated above, FIGS. 1A-1D are provided merely as examples. Other examples may differ from what is described with regard to FIGS. 1A-1D.

FIGS. 2A-2B are diagrams of examples 200 of light-current (L-I) curves associated with optical devices.

FIG. 2A shows an L-I curve 202 associated with an optical device that does not include the pair of trenches 122 and the pair of grooves 124 described herein. The optical device may, for example, have a width of 400 micrometers (μm) and a length of 4.8 mm, and a ridge of optical device may have a width of 250 μm and a length of 4.8 mm. Accordingly, the optical device may have a fill factor of 62.5% (e.g., 250 μm divided by 400 μm). As shown in FIG. 2A, the L-I curve 202 includes a kink 204, where a power (an optical power, in Watts (W)) of the optical device decreases as a current (in Amps (A)) applied to the optical device increases (e.g., when the current applied to the optical device increases from approximately 9 A to 10 A). As further shown, the L-I curve 202 is not smooth, such that an incremental change in the current may result in more than, or less than, an incremental change in the power of the optical device. Consequently, a power performance of the optical device (e.g., when changing the current that is applied to the optical device) is not consistent or predictable. Further, in some cases, applying an increased current results in a reduced power of the optical device.

FIG. 2B shows an L-I curve 206 associated with an example configuration of the optical device 102, which includes the pair of trenches 122 and the pair of grooves 124 described herein. The optical device 102 may, for example, have a width of 400 μm and a length of 4.8 mm, and the ridge 126 of the optical device 102 may have a width of 250 μm and a length of 4.8 mm. Accordingly, the example configuration of the optical device 102 may have a fill factor of 67.5% (e.g., 270 μm divided by 400 μm). As shown in FIG. 2B, the L-I curve 206 does not include a kink. Further, the L-I curve 206 is smooth, such that an incremental change in current applied to the optical device 102 results in an incremental change in a power of the optical device. Accordingly, a power performance of the optical device 102 (e.g., when changing the current of the optical device) is more consistent and predictable than that of the optical device described herein in relation to FIG. 2A. Further, the power performance of the optical device 102 is more efficient because applying an increased current to the optical device 102 results in an increased power of the optical device 102.

As indicated by the L-I curve 206, the optical device 102 provides an improved power performance as compared to that of the optical device described herein in relation to FIG. 2A. This is because the optical device 102 includes the pair of grooves 124 that are configured to minimize, or prevent, formation of ring modes and/or other non-preferred in-epi-plane lasing modes within the epitaxial layer structure 106 of the optical device 102 (e.g., as described herein). In this way, current applied to the optical device 102 is used to form a preferred lasing mode of the optical device 102. Accordingly, in many cases, the optical device 102 provides a higher power per Amp than a similar optical device that does not include the pair of grooves 124.

As indicated above, FIGS. 2A-2B are provided merely as examples. Other examples may differ from what is described with regard to FIGS. 2A-2B.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical device, comprising:
a substrate;
an epitaxial layer structure disposed over the substrate that includes:
a first clad layer disposed over the substrate,
a first waveguide layer disposed over the first clad layer,
an active layer disposed over the first waveguide layer,
a second waveguide layer disposed over the active layer,
a second clad layer disposed over the second waveguide layer, and
a cap layer disposed over the second clad layer;
a pair of trenches formed in an inner region of a surface of the epitaxial layer structure; and
a pair of grooves, each formed in an outer region of the surface of the epitaxial layer structure.

2. The optical device of claim 1, wherein:
each trench, of the pair of trenches, extends into at least the second clad layer, and does not extend into the active layer; and
each groove, of the pair of grooves, extends through the cap layer, the second clad layer, and the second waveguide layer, and into the active layer.

3. The optical device of claim 1, wherein a fill factor of the optical device is greater than or equal to 60%.

4. The optical device of claim 1, wherein the optical device is a broad area laser device configured to emit a near infrared laser beam.

5. The optical device of claim 1, wherein the pair of trenches are configured to cause a slow axis far field divergence angle associated with the optical device to be less than or equal to 10 degrees.

6. The optical device of claim 1, wherein each groove includes a sidewall that is at least one of:
rough;
non-planar; or
oriented at a non-zero angle to an emission axis of the optical device.

7. The optical device of claim 1, wherein the pair of grooves are configured to cause a light-current curve associated with the optical device to not include a kink.

8. The optical device of claim 1, wherein the pair of grooves are configured to cause a light-current curve associated with the optical device to be smooth.

9. An optical device, comprising:
an epitaxial layer structure that includes an active layer;
a pair of trenches formed in an inner region of a surface of the epitaxial layer structure; and
a pair of grooves formed in outer regions of the surface of the epitaxial layer structure,
wherein each groove, of the pair of grooves, has a depth that is greater than a depth of each trench of the pair of trenches.

10. The optical device of claim 9, wherein a fill factor of the optical device is greater than or equal to 60%.

11. The optical device of claim 9, wherein the optical device is configured to emit a laser beam associated with a spectral range of 700 to 1600 nanometers.

12. The optical device of claim 9, wherein:
each trench, of the pair of trenches, does not extend into the active layer; and
each groove, of the pair of grooves, extends into the active layer.

13. The optical device of claim 9, wherein a slow axis far field divergence angle associated with the optical device is less than or equal to 10 degrees.

14. The optical device of claim 9, wherein each groove includes a sidewall that is at least one of:
rough;
non-planar; or
oriented at a non-zero angle to an emission axis of the optical device.

15. The optical device of claim 9, wherein a light-current curve associated with the optical device does not include a kink.

16. The optical device of claim 9, wherein a light-current curve associated with the optical device is smooth.

17. A laser device, comprising:
an epitaxial layer structure;
a pair of trenches formed in an inner region of a surface of the epitaxial layer structure; and
a pair of grooves formed in outer regions of the surface of the epitaxial layer structure.

18. The laser device of claim 17, wherein:
each trench, of the pair of trenches, does not extend into an active layer of the epitaxial layer structure; and
each groove, of the pair of grooves, extends into the active layer of the epitaxial layer structure.

19. The laser device of claim 17, wherein a slow axis far field divergence angle associated with the laser device is less than or equal to 10 degrees.

20. The laser device of claim 17, wherein a light-current curve associated with the laser device is at least one of:
kink-free, or
smooth.
